(19) United States
(12) Patent Application Publication
(10) Pub. No.: US 2010/0300509 A1
(43) Pub. Date: Dec. 2, 2010

(54) Solar photovoltaic modules with integral wireless telemetry

(76) Inventors: Douglas William Raymond, Orinda, CA (US); Gary Stofer, Concord, CA (US)

Correspondence Address: Douglas W. Raymond, 23 Martha Road, Orinda, CA, 94563, US

(21) Appl. No.: 12/800,917

(22) Filed: May 26, 2010

Related U.S. Application Data
(60) Provisional application No. 61/217,055, filed on May 26, 2009.

(51) Int. Cl. H01L 31/042; G01R 19/00

(52) U.S. Cl. 136/244; 324/76.11

(57) ABSTRACT

The invention provides a solar photovoltaic (“PV”) module with integral wireless measurement and telemetry, transmitting to a central gateway node. It also provides a solar array constructed using these improved modules and network. These wirelessly monitored modules and the network in which they communicate allow the important state variables of individual modules to be observed remotely, without direct physical access to the array. The monitors measure and report the module voltage, and may also be designed to measure current flow, temperature, and/or other variables of interest. The invention offers valuable savings by immediately revealing trouble, by diagnosing to the specific location of a fault, by reducing losses due to module and string downtime, by reducing labor and capital equipment devoted to ongoing operation and maintenance, and by speeding troubleshooting during initial commissioning of newly built arrays.

This Non-Provisional Application refers to an earlier-filed Provisional Application of the same name, filed by the same inventors. Our postcard receipt for the Provisional Application bears reference number “61217055” and a filing date of “052609.”

### Inventors:

Douglas W. Raymond, 23 Martha Road, Orinda Calif. 94563
Gary Stofer, 1753 Landana, Concord Calif. 94519

### BACKGROUND

The greatest growth segment for solar photovoltaic (“PV”) arrays in the past decade has been in so-called “grid-tied” installations. Such “grid-tied” PV systems are typically used to provide supplementary power (often for refrigeration loads such as air conditioning) during peak sunlight periods. These peaks conveniently coincide with peak utility pricing. There are generally no storage batteries in a grid-tied system other than keep-alive batteries to sustain subsets of operation (e.g. timekeeping) during periods of darkness and during grid outages. Power generated by the PV system supplements power drawn from the grid. Excess power from the PV array, if any, is fed back into the grid: the utility achieves a fuel saving at the utility, and the saved fuel acts as a community storage battery. Our invention can be used with off-grid PV systems as well, but we predict it will confer its greatest social benefit in grid-tied systems. Residential installations as small as one or two kilowatts are becoming common, and many institutional installations are known that exceed several megawatts.

Many sources of information on solar photovoltaics exist, and will be found useful by anyone who is skilled in the art and interested in making the invention which we describe here. Some common information sources for solar photovoltaics that are current at the time of this writing are listed here. It is a rapidly evolving field, so the trade journals and professional associations are better sources than bound books. A reader skilled in the art and seeking to make our invention is therefore advised to explore additional sources:
American Solar Energy Society, 2400 Central Ave, Suite A, Boulder Colo. 80301 http://www.ases.org/
Solar Today Magazine, published by American Solar Energy Society http://www.solartoday.org/
Home Power Magazine, Box 520, Ashland Oreg. 97520 http://www.homepower.com/home/7/2/2010
Photon International Magazine, Solar Verlag GmbH, Juelicher Strasse 376, 52070 Aachen, Germany http://www.photon-international.com/

### Electrical Arrangement

A PV “array” consists of several modules, each module consisting of cells. Ordinarily, several modules are wired in series to form a “string,” and an array is made by parallel-connecting several such series-connected strings of modules. In most arrays, each string has the same number of modules, so the no-load voltage for each string is approximately the same. The strings being connected in parallel, each string adds its current to the common sum. Thus all parallel-connected strings operate at same working voltage, regardless what their no-load voltages were.

A string, being a series circuit, will fail when any of its cells or modules fails, such as when a cell or module is compromised by damage, shadowing, contamination, as well as corrosion or shorting of the connecting wiring. Manufacturing defects in solar modules are rare, but they are also a finite fraction of the total fault spectrum. Any fault that takes out a module takes out a whole string, because the no-load voltage for that string will be less than the working voltage for the array. Thus any fault condition that takes out a string causes a decrease in the amount of power produced by the array. The loss of a child's toy on a rooftop can therefore be more important than it once was, if the roof is now serving as a PV power generator in addition to its conventional purposes.

### Limitations of Prior PV Modules

The decrease in output due to a new fault may not be noticed immediately. Light and cloud conditions also vary from time to time and day to day. These ordinary and expected variations may be so large that they mask the variation caused by the new string failure, leaving it unnoticed for weeks or months. Routine visual inspection is only a partial remedy. It is difficult in many cases, due to the fact that the modules are typically mounted on elevated structures such as rooftops. Further, some kinds of faults are not visible to the human eye. It should be clear, therefore, that failures occur, and that they can go undetected for periods of time, resulting in lost opportunity to deliver energy.

Conventional PV modules are not automatically monitored. Indeed, if multiple strings are hardwired in parallel with one another, as is usual, even the individual string currents cannot be determined without opening the array one string at a time. When a faulty string is identified, the serviceperson still does not know which module or wire is faulty.

Troubleshooting a series-connected string is inherently troublesome and time-consuming. Troubleshooting work on PV arrays can be especially dangerous because the modules are often mounted on elevated structures, and because the series connection of multiple modules creates dangerously high DC voltages.

As will be shown, our invention will allow the main work of inspection, fault detection and diagnosis to be done from afar, eliminating both the danger and the labor cost that would have been consumed in inspecting and troubleshooting an array of conventional modules.

### Approaches to Monitoring

Wire-based methods of monitoring individual modules and reporting data to a service location can be envisioned. Some wire-monitored arrays may even exist, though we are not aware of any successful systems that work in that way. For terrestrial installations, wire-based monitoring is so expensive that its advantages do not repay its costs. Installing sensing wiring to the module level, though possible, is prohibitively expensive, because such wiring has high voltages and must be run in armored conduits. Even if wiring were free of cost, ground-offset issues require high-voltage sensing circuits with very good common mode rejection. This makes the sensing circuits more expensive than if all modules had a common ground reference. Being series-connected, each module in the string is offset from Earth ground by the sum of the working voltages of the modules between it and Earth. For example, if there are eight 40-volt modules in a string, the top module's voltage would have to be measured as a 40-volt differential against a 280-volt ground offset. Detection of a small change in the 40-volt output against the 280-volt common mode offset is not an impossible task, but it requires more expensive circuits than are required by our invention. Added wiring is additional stuff that may go wrong, and may even cause faults in the array that would not have otherwise occurred. Because of these added costs and encumbrances, PV modules in most arrays today are not individually monitored.

We have also been informed of a different kind of solar array, in which each module contains an integral inverter. Such a system is made by the EnPhase company of Novato, Calf., i.e. http://www.enphaseenergy.com/. The modules, having integral inverters, produce AC outputs, rather than DC outputs. The AC outputs are wired in parallel to the outputs of other modules in the array. An inverter—even a small one—must contain a lot of circuitry just to make AC out of DC and to control the process. Most modern inverters measure current and voltage, in order to adjust its conversion parameters to seek the loading condition where the load receives the most power. In this kind of system, each module supports circuits to measure, to calculate and to perform arithmetical and logical operations. To add a networking interface, wired or wireless, would be natural in such a system, since its incremental cost would be small compared to the far greater incremental cost of the integral inverter. Our invention, it should be noted, uses a very small amount of circuitry per module, and has far less incremental cost than an integrated inverter. We intend it to apply only to plain DC modules, and to arrays containing them, not to so-called “microinverter” systems.

### OBJECTS OF OUR INVENTION

The principal object of our invention is to provide the economic benefits of monitoring of individual DC-output PV modules in an array, and to do it without introducing any difficulties that would interfere with its commercial adoption.

### SUMMARY OF OUR INVENTION

The present invention provides PV modules into which wireless monitors are integrated before the array is constructed, and preferably as part of the module assembly process.

The improved PV modules are combined as usual into an array containing multiple modules as parallel strings of series-connected modules. The monitors use wireless methods such as radio or optics to transmit their measurements. The monitors observe voltage and other parameters. Each monitor is powered by the PV module that it is an integral part of. A gateway node located within radio range of the array, connects the network of monitors to an external network, so that the condition of the array, strings and modules can be inspected from a distant location that has communicative access to the gateway node. The gateway node's outside network is ordinarily a wired network, but in fact it may also be wireless, e.g. communicating to a “Wi-Fi” hot spot. In a remote location, the gateway node may be connected to a microwave transponder.

As will be readily understood by anyone skilled in the art, the exact details of the network inside the array or outside the gateway are not important to the understanding of the invention, or to its construction: departures from what we describe here are permissible within the spirit of the invention. Information about wireless networking is readily available. It is a rapidly growing business area, so the business environment is evolving: the future may provide offerings even better than the two listed here. The person skilled in the art who seeks to make our invention is therefore advised to make a new search, possibly discovering a network implementation even more appropriate to his or her needs, or possibly making use of an already-existing business relationship.
Dust Networks, 30695 Huntwood Avenue, Hayward Calif. 94544 http://www.dustnetworks.com/
Texas Instruments (various addresses) http://focus.ti.com/docs/toolsw/folders/print/simpliciti.html

The monitor at an individual module measures the module's voltage (and possibly other relevant physical signs such as current and temperature), digitizes the measurements, and transmits the data wirelessly to a gateway node.

The gateway node collects data from multiple modules in the array. Processes in the gateway node manipulate the data to make it usable. Example processes may include: store and retrieve the data; organize the data into a regular format; operate analytical algorithms for assessing array and module performance; present data to a conveniently located human interface; transmit the data to more distant locations; and the like. In the preferred embodiment, the gateway contains a web server process and interface to the worldwide web (“web”). Thus the gateway makes the data in its manipulated form available to clients or other gateways anywhere in the world. The server can be secured, if necessary, to prevent unauthorized access.

The circuitry in the gateway node can be ground-referenced: it is not wired to the modules themselves.

Methods of measuring voltage, current, temperature and so forth are so well known in the art of electronic design, that we find it unnecessary to cite references or provide refined circuit designs in this specification. In the detailed description, we will cite references only for some of the components we happened to choose for our embodiment.

### What Parameters are Measured and Reported

The primary parameter is voltage. The reason for measuring and reporting voltage is clear: damage, soiling, shading and manufacturing defects are all faults that will negatively affect a module's output voltage. Thus a report of an abnormally low voltage from one module while other modules report normal voltages suggests a need for maintenance attention to the specific module that is exhibiting a low voltage.

Secondarily, an abnormally high or low temperature measurement suggests trouble worth a personal visit. Module efficiency, for mono- and polycrystalline silicon modules decreases with increasing temperature. Shading of cells can cause local heating, as well, so an unusual temperature reading, different from the temperatures of nearby modules, calls for on-site investigation.

Our invention provides a means for measuring and reporting current as well. Ideally, the magnitude and direction of the current should be equal for all modules in a string. If the current in part of the string differs from the current in another part of the string, the usual cause is a wiring error or damage to insulation, wiring or connector, resulting in undesired leakage of current to Earth or to another circuit point. When our invention is used to report individual module current readings, the array manager can easily detect a current fault and localize it to an individual connection in the array. In arrays of conventional modules that do not monitor individual module currents, such faults may go undetected for long periods of time. Once current faults are suspected, considerable amounts of skilled labor must be committed to their diagnosis. When current is leaking from the array at any point, servicing the array poses additional risks of human electrocution.

It is, of course, possible to build our invention without the current monitoring circuits, and also possible to use a version of our invention that contains the current monitoring circuits without paying attention to the current readings. The installation can be set up to choose one module per string as the current sensor and ignore the others. Some small economy may be achieved by defeating the actual measurement on all but one of the modules in a string, e.g. by not installing certain components or firmware, but this is probably not worth the trouble of making some modules different from others. It may be better to do it in software, by simply ignoring the readings that are not needed.

Additional details are provided in the “Description” below. In the invention as described here, all monitored modules in an array are equipped to measure voltage, current and temperature. Other arrangements, including partial implementations, or implementations in which additional parameters are reported, are possible without departing from the spirit of our invention.

### Advantages of our Invention over Conventional PV Modules

A PV array constructed from monitored modules offers clear advantages over conventional unmonitored modules. Faults in modules are detected immediately, and localized automatically, without danger to personnel. Lost power is almost entirely eliminated. Labor is dramatically reduced, because routine periodic inspection is not necessary. Risks to personnel from falls or electrocution are reduced. Cost of damage to installed equipment from personnel falling, misstepping and dropping tools is reduced. Capital cost of service equipment, facilities and vehicles is far less than with conventional modules.

In addition to being useful for ongoing monitoring over the life of the array, our invention is particularly useful when running quality checks on a newly constructed array, or one which has received substantial modifications.

A further advantage is in our use of wireless technology to collect data from the monitors: by making the monitors wireless, we eliminate monitor design problems associated with high common mode voltages and removal of ground offsets.

Yet another advantage comes from our invention's use of the PV module's output to power the monitor. This eliminates power wiring as well as signal wiring, and indeed eliminates the need for any monitor-related wiring at all. It therefore makes it possible to design and construct an array of our improved modules at substantially the same cost as for an array of conventional modules.

The physical integration of our monitors into the modules themselves is advantageous, in that it protects their circuits from the elements, and prevents accidental human contact with the high voltages present in them.

Integration makes it possible to use conventional mounting and wiring practices in the construction of the array. Thus the technological evolution from conventional modules to wirelessly monitored modules is straightforward, and requires only minimal new training for array designers and installers.

A subtle, but potentially immense, benefit is in the fact that the gateway node can be accessed electronically from a distant location. Indeed, the gateway node that collects module data can be of the type that makes the data visible on the worldwide web. Thus, the data for arrays, strings, modules, etc. can be accessed from anywhere in the world. The effectiveness of personnel is thereby multiplied: a small team can effectively supervise a large number of arrays at widely separated locations, dispatching human service personnel only when really necessary. Additionally, redundant supervision is possible, if an individual gateway can be accessed from more than one service center.

### Summary of Drawings and Numbered Items

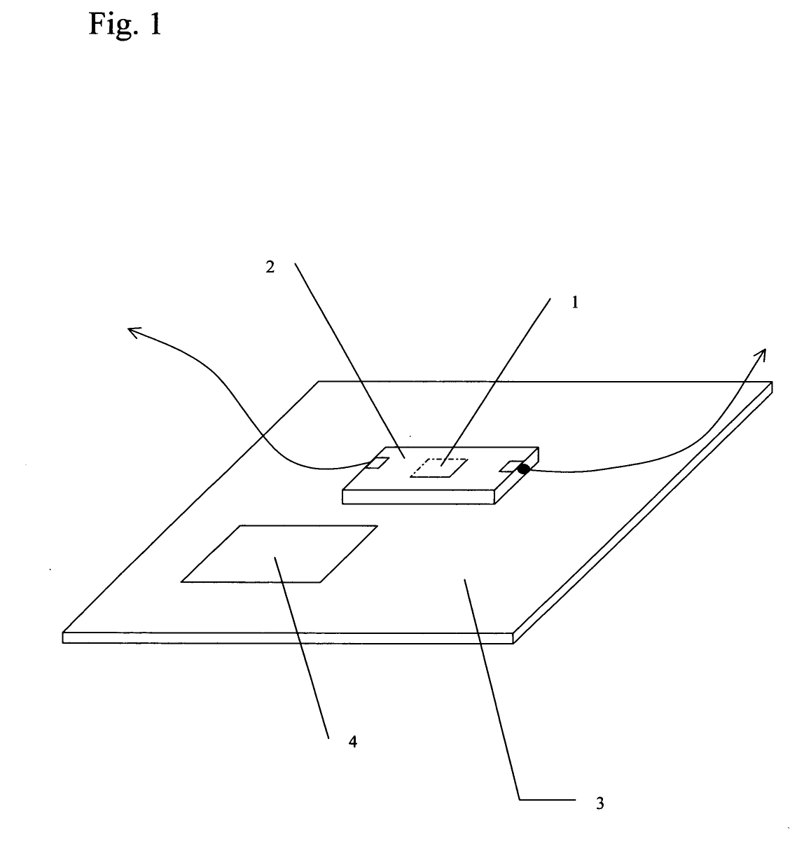

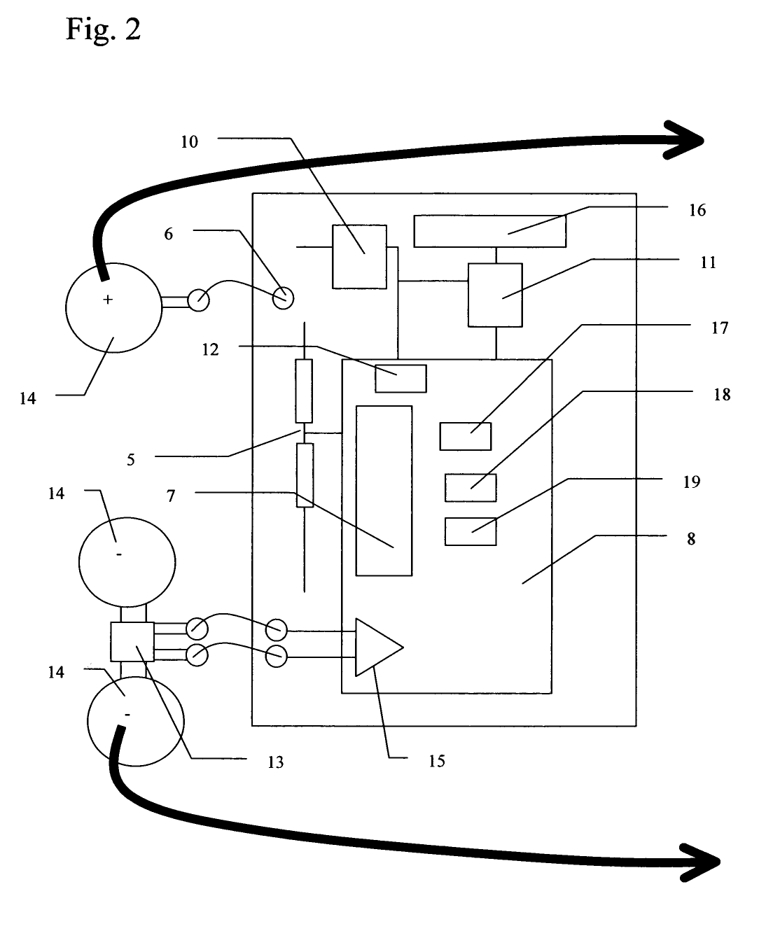

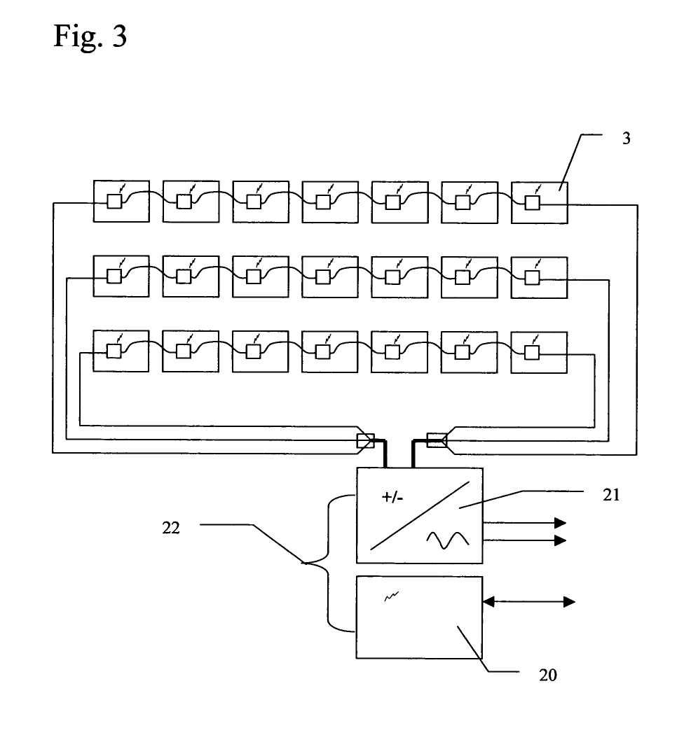

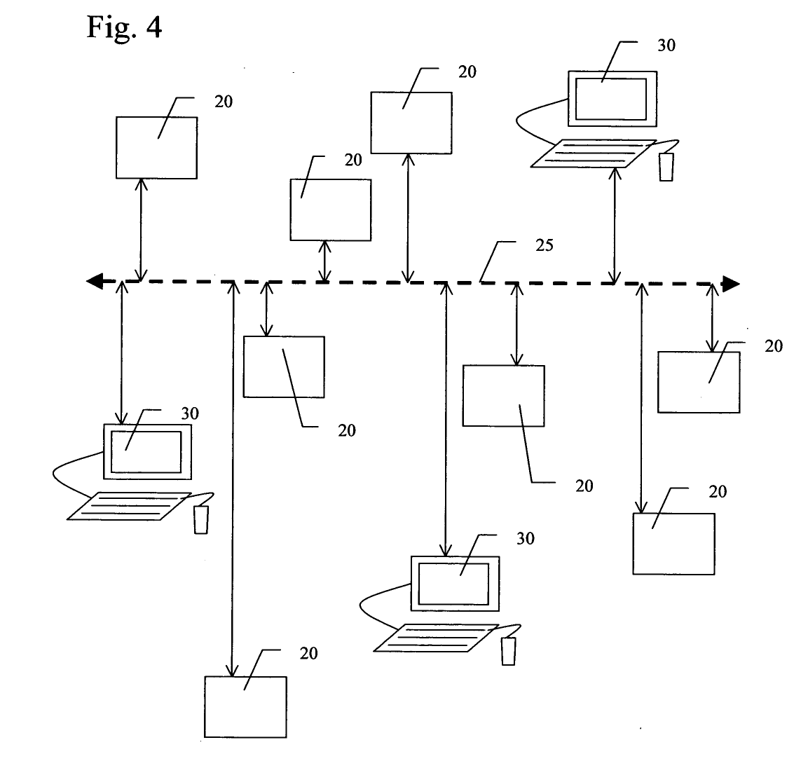

Four sheets of drawings are provided, with enumerated items as follows:

| | | | | FIG. 4 | |
|---|---|---|---|---|---|
| | | FIG. 2 | FIG. 3 | (Wide-area | |
| | FIG. 1 | (Monitor Block | (Array Block | Supervising System | |
| | (Back of Module) | Diagram) | Diagram) | Block Diagram) | |
| | This item appears | This item appears | This item appears | This item appears | Descriptive Name |
| Item | in FIG. 1? | in FIG. 2? | in FIG. 3? | in FIG. 4? | of numbered item |
| 1 | Yes | | | | Monitor |
| | | | | | Electronics |
| | | | | | Assembly |
| 2 | Yes | | | | Junction Box |
| 3 | Yes | | Yes | | Solar PV Module |
| | | | | | with wireless |
| | | | | | network interface |
| 4 | Yes | | | | Nameplate |
| 5 | | Yes | | | Resistive Divider |
| 6 | | Yes | | | Module output |
| | | | | | voltage terminal |
| 7 | | Yes | | | Digitizer |
| 8 | | Yes | | | Microcontroller |
| 9 | | | | | Number not used |
| 10 | | Yes | | | Voltage regulator |
| 11 | | Yes | | | Radio circuit |
| 12 | | Yes | | | Temperature sensor |
| 13 | | Yes | | | Current Sensing |
| | | | | | Resistor |
| 14 | | Yes | | | Solar module |
| | | | | | connection terminals |
| 15 | | Yes | | | Amplifier |
| 16 | | Yes | | | Antenna |
| 17 | | Yes | | | Read-only memory |
| 18 | | Yes | | | Random-access memory |
| 19 | | Yes | | | Timer |
| 20 | | | Yes | Yes | Gateway node |
| 21 | | | Yes | | Grid-tied inverter |
| 22 | | | Yes | | Improved grid- |
| | | | | | tied inverter |
| 23-24 | | | | | Numbers not used |
| 25 | | | | Yes | Network medium |
| 26-29 | | | | | Numbers not used |
| 30 | | | | Yes | Supervising Station |

### DESCRIPTION

### First, Packaging, Referring to FIG. 1:

FIG. 1 is a view of the back of the module, the wiring side. Ordinarily this side is underneath, and the solar-sensitive side is on top. The monitor electronics assembly [1] is a surface-mount circuit board 3 cm by 3 cm. It is mounted securely inside the junction box (“J-Box”) [2] on the back of the module [3]. The nameplate [4] ordinarily contains manufacturer, model number and specification information, including a serial number and a bar code. Many module manufacturers maintain databases containing factory test results for each individual module.

### Second, Block Diagram of the Monitor, FIG. 2:

As noted earlier, electronics is a field with rapid changes, so the detail design may change over time to use more currently fashionable components. This block diagram is sufficient to enable a person skilled in the art to make the invention, without confining him or her to the component libraries and conventions that prevail at the time of our disclosure.

A resistive divider [5] reduces the 40-volt module output voltage [6] to a level suitable for input to the digitizer [7]. The digitizer is an internal functional block of the microcontroller [8]. The resistance values in the divider are chosen according to the module's voltage range and the power rail voltage for the microcontroller. The resistance values should be as high as possible to avoid robbing power from the module while not being so high as to limit the accuracy of the measurement.

Voltage regulator [10] provides steady voltage to the microcontroller and wireless circuits, irrespective of changes in the module output.

Radio circuit [11] is the communication interface between the monitor and the rest of the network.

Temperature sensor [12] is an internal function of the microcontroller. Its signal is digitized by digitizer [7].

Current sensing resistor [13] is as low a value as practicable, in order not to waste power. For example, a 0.001 ohm resistor would generate 5 millivolts at 5 amperes. This is enough to measure, and the power dissipated would only be 25 milliwatts, a tiny fraction of the module power, which is many thousands of times as large. Other resistor values are permitted within the spirit of the invention, and are best chosen by the individual designer according to his or her specific situation. The resistor is best located as far as possible from the microcontroller on the circuit board, so its heat will not throw off the temperature measurement made by a sensor in the microcontroller. It is mounted to the module substrate, not to the monitor circuit board. It is a four-terminal type, constructed so that accurate Kelvin-style measurements can be made in the face of irregular mounting or soldering conditions. Additionally, the solar module's connecting terminals [14] act as heat conductors, creating an essentially isothermal zone that includes the resistor and the solar cells. This arrangement ensures that the measurements made by the temperature sensor can be relied on as representative of the solar cells themselves.

Amplifier [15] is an internal functional block of the microcontroller. It amplifies the current signal to a level appropriate for digitizing by digitizer [7]. If the current function is not to be used, the module output cable can be attached to the “upper” end of the current sensing resistor, in which case there will be no current in the resistor.

Antenna [16] is a ceramic component soldered to the circuit board. Other antenna design choices are possible. If space permits, traces on the circuit board could be made to serve as antennas.

Read-only memory [17] is an internal functional block of the microcontroller. This memory contains code to operate the monitor. It also stores constants that are unique to the module, to the module manufacturer, to the date of manufacture, to the calibration of the sensing circuits, and the like. The list of constants may include a unique identifying number linking the monitor permanently to the PV module of which it is an integral part: this identifier will be helpful in establishing the network and in identifying which module is the source of any given data packet.

Random-access memory [18] is an internal functional block of the microcontroller. It is used for temporary storage of variable data used in calculations, and in manipulating packets for network communication.

Timer [19] is an internal functional block of the microcontroller. It runs when the microcontroller is sleeping, and provides a periodic signal to wake the microcontroller up. Effective use of our invention does not demand a high data rate. For the sake of keeping the power usage to a minimum, the monitor stays in a low power inactive mode most of the time, and only wakes up periodically; for example, the monitor—or the network as a whole—could be programmed to wake only once every several minutes, be active for a few milliseconds, and then return to its low power idle state. In this way, average power consumption can be very low even though the transmission power can be as high as needed to ensure reliable communication.

In our embodiment, the microcontroller is the Texas Instruments MSP430 series, and the radio IC is the Texas Instruments CC2500 series. The ceramic antenna is from the W\tilde{v}rth Electronik Group, www.we-online.com. The general layout is that recommended by Texas Instruments with their development kit EZ430-RF2500 Quick Start. A similar chip set and development environment can be obtained through Dust Networks, at an address noted above.

We remind the reader that during the term of this patent, many improvements in electronic technology are expected: we would not be surprised one day to find components presently shown as peripheral to the microcontroller package integrated into it. Such a development would in no way depart from the spirit or scope of our invention.

Example details of the wireless network and how it gets established on power-up are described in the literature supplied by Texas Instruments and/or Dust Networks, and will not be described here, save to say that their two approaches are quite different from each other, but either can be made to work within the spirit of our invention. The person implementing this invention in the future is expected to be skilled in the art of embedded system design, and to be knowledgeable about wireless networking. He or she will have additional resources available that do not yet exist at the time of this writing, and is therefore encouraged to use microcontrollers, radios, antennas and networking features that are suitable to his or her individual situation.

### Third, Block Diagram of an Assembled Array, FIG. 3:

The figure shows an array of twenty-one modules [3] arranged in three paralleled strings of seven modules each, combined to feed a single grid-tied inverter. Each module contains a monitor after [1] in FIG. 1, which transmits voltage, current and temperature information to gateway node [20].

Inverter [21] is a conventional grid-tied inverter. Many such inverters in today's inverter marketplace have interfaces to external networks. It would be possible to modify the design of a conventional inverter by incorporating the gateway node of our invention into it. This improved inverter is depicted as item [22], which combines items [20] and [21].

### Fourth, Block Diagram of a Wide-area Supervising System, FIG. 4:

Network medium [25] such as the World-Wide Web (“WWW”) provides communicative interconnect of multiple gateways [20] and multiple supervising stations [30]. WWW technology is well know to those skilled in the networking art, and will not be described here in any further detail Furthermore, the implementer of our invention may choose to use a network other than the WWW, in which case any more detailed description would be spurious.

A supervising station provides a operation and maintenance supervisor with capability of viewing one or more arrays through the agency of their gateways. The supervising stations can be ordinary personal computers that have hardware and software for access to the web, such as a Microsoft Windows-based PC or an Apple Mac-style computer running a web browser such as Internet Explorer, Safari or Firefox. Individual designers will make choices, and note that is it is not our intent to limit future implementers to the architectures that predominate today; better ones are sure to come into existence. Trans-platform software environments such found in modern browsers make it possible to support a heterogeneous population of supervising stations.

Anyone with worldwide web knowledge can easily see that it is possible to provide software access between any supervising station and any gateway, when all supervising stations and all gateways are communicatively connected to the web. It can also be seen that it is also possible to configure groups, and to control access by passwords, so that specific groups can overlap with other groups, or specifically exclude other groups. Thus it is possible to set up a business arrangement in which one maintenance crew supervises one or more solar arrays, or in which any given solar array can be supervised by one or more maintenance crews, or combinations of both arrangements.

Computing power and storage in the computer of the supervising station [30] is used for many purposes, including but not limited to storing and analyzing data transmitted by gateways. Logic capabilities in the computer of the supervising station allow the running of useful algorithms, e.g. for logging performance of modules, strings and arrays, for logging of response times to service requests, and for automatically sending bills and other form letters. Other useful functions that can be entertained include automatically detecting faults in a module, string or array, and initiating a service request.

It is acknowledged that the invention will be implemented by people skilled in the relevant arts, and that they will have great variety of choice available to them as regards the various features of physical module construction, monitor subassembly design and construction details, choice of integrated circuits, design of networking technology, intelligence level of alarm algorithms, and degree of marriage with other features of the installation. Many choices can be made as to the inverter and as to any subsystem(s) that communicate with the supervising world, outside the gateway. Accordingly, although we have provided enough of a description here to enable anyone skilled in the art to make and use the invention, it will not be of further assistance for us to enumerate any more choices or to prescribe any more details of our embodiment. The scope of the invention is most precisely defined by the following claims.

We claim:

1. A solar photovoltaic array for grid-tied applications, composed of photovoltaic modules, in which
a. each module produces DC voltage and current, and
b. groups of modules are wired as series strings, and
c. groups of series strings are wired in parallel, monitors, integrated into the photovoltaic modules, which measure the output voltages of the individual modules and report the measurements wirelessly to a gateway node.

2. A DC-output solar photovoltaic module for combining into an array of parallel-connected series strings, said module containing an integral wireless monitor for wirelessly reporting the module's output voltage to a gateway node.

3. A supervision network for supervising one or more grid-tied solar arrays, containing one or more computer-based supervising stations;
each grid-tied solar array containing two or more parallel strings of series-connected DC photovoltaic modules;
said series-connected photovoltaic modules having integrated wireless monitors for wirelessly reporting module voltage.
